(19) United States
(12) Patent Application Publication
(10) Pub. No.: US 2009/0119039 A1
(43) Pub. Date: May 7, 2009

(54) Approach for Controlling Electrical Power

(75) Inventors: James A. Banister, Park City, UT (US); Francis Kim, Philadelphia, PA (US); Angela Lee Arnold, Philadelphia, PA (US)

Correspondence Address: ALLEMAN HALL MCCOY RUSSELL & TUTTLE LLP, 806 SW BROADWAY, SUITE 600, PORTLAND, OR, 97205-3335, US

(73) Assignee: SPROUTLETS, INC., Park City, UT (US)

(21) Appl. No.: 11/936,550

(22) Filed: Nov. 7, 2007

(51) Int. Cl. G01R 21/133

(52) U.S. Cl. 702/62

(57) ABSTRACT

An electrical power metering system. The electrical power metering system may include a plurality of gated power receptacles, each of the gated power receptacles being configured to selectively provide electrical power in response to receiving a wireless signal. The system may further include a service application configured to receive a request to provide electrical power for one of the plurality of gated power receptacles, the request including an identifier that designates the one of the plurality of gated power receptacles at which electrical power is requested. The system may further include a local host application executable on a computing device, the local host application being configured to send the wireless signal via a coordinator module to the one of the plurality of gated power receptacles to provide electrical power in response to receiving a communication from the service application that includes the identifier.

### BACKGROUND

Due to advances in portable electronic device technology, there exists an increasing tendency for individuals to use electronic devices at locations away from the home or office. In some cases, a portable electronic device may be connected to an electrical power outlet in order to provide power the portable electronic device. For example, an individual may connect the power cord of a laptop computer to an electrical power outlet of a business, such as a coffee shop or an airport, in order to power the laptop computer or recharge the battery of the laptop computer. Over time, due to the proliferation of portable electronic devices, establishments such as these may provide a large amount power to visitors that plug in portable electronic devices to outlets of the establishment, which may result in higher operating costs.

### SUMMARY

An electrical power metering system is provided. The electrical power metering system may include a plurality of gated power receptacles, each of the gated power receptacles being configured to selectively provide electrical power in response to receiving a wireless signal. The system may further include a service application configured to receive a request to provide electrical power for one of the plurality of gated power receptacles, the request including an identifier that designates the one of the plurality of gated power receptacles at which electrical power is requested. The system may further include a local host application executable on a computing device, the local host application being configured to send the wireless signal via a coordinator module to the one of the plurality of gated power receptacles to provide electrical power in response to receiving a communication from the service application that includes the identifier.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 shows a schematic view of one embodiment of an electrical power metering system having gated, metered electrical power receptacles.

FIG. 2 shows a schematic view of one embodiment of a gated power receptacle adaptor of the system of FIG. 1.

FIG. 3 shows a communication flow diagram demonstrating an example of selectively providing electrical power at a designated gated power receptacle based On a user request.

FIGS. 4A-4B show a flowchart of one embodiment of a method for selectively providing electrical power at a designated gated power receptacle based on a user request.

FIG. 5 shows a schematic view of one embodiment of a multigated power receptical grouped into one or more power distribution units.

### DETAILED DESCRIPTION

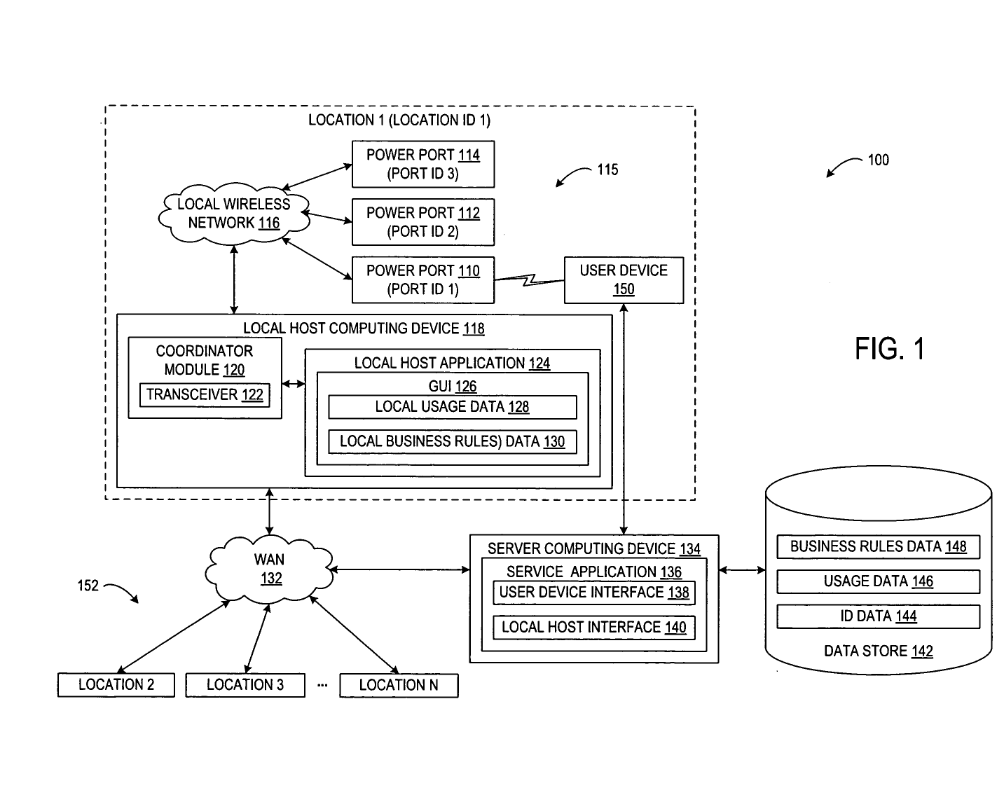

FIG. 1 illustrates an electrical power metering system 100 for controlling distribution of electrical power. System 100 includes a plurality of gated power receptacles 110, 112, 114 at a first location, such as a coffee shop, airport, or other location with accessible power receptacles. The gated power receptacles may be alternatively referred to as power ports and may be generally referenced by 115. Each of the gated power receptacles may be designated with a gated power receptacle identifier (e.g., PORT ID1—power port 110, PORT ID2—power port 112, PORT ID3—power port 114). Further, the gated power receptacles may be grouped according to a location identifier (e.g., LOCATION ID1—first location). In some embodiments, the gated power receptacle identifier may include the location identifier. By including the location identifier in the gated power receptacle identifier, each gated power receptacle at each location maybe identified.

Each of the plurality of gated power receptacles 115 may selectively provide electrical power to respective electrical devices in response to receiving a wireless command signal. The wireless command signal may be based on a request by a user to provide power at a desired gated power receptacle to power an electrical device of the user. The request may include a location identifier and a gated power receptacle identifier so that the correct gated power receptacle at the correct location may be identified to provide power.

In one example, the request may be generated via user device interface 138 of a service application 136 executable on a server computing device 134. In particular, user device interface 138 may be presentable on user device 150 and a user may input the request via the user device. In some cases, the server computing device may serve the user device interface via a so-called “thin” client to the user device.

It will be appreciated that user device 150 may be any suitable device capable of wireless communication. For example, the user device may be a cellular phone, or a portable computing device such as a laptop computer. Further, the user device interface may be configured to receive and process the request. For example, the user device interface may include interactive voice response (IVR) technology and the request may be spoken by the user and recorded by the service application. As another example, the user device interface may include simple message service (SMS) technology and the request may be a text-based message. As yet another example, the user device interface may include a graphical user interface that may be served to a web client application, such as internet browser, and the request may be made using the hyper text transfer protocol (HTTP).

Note, user device 150 from which the request for electrical power may be generated may be a different device than the device plugged into the gated power receptacle. Although it will be appreciated that the request in some scenarios may be generated from the same device that is plugged into the gated power receptacle.

Upon receiving a request from a user device, service application 136 may be configured to send a communication to a local host application via a wide area network (WAN) 132. The communication may be sent to a local host application based on the location identifier provided in the request from the user device. Further, the communication may include the gated power receptacle identifier and a command to turn on electrical power at the gated power receptacle. In particular, service application 136 may be in communication with data store 142. Data store 142 may include identification data 144 that includes all of the location identifiers and gated power receptacle identifiers in the system. In some embodiments, the identification data may be organized according to look up tables which may be accessed by the service application.

It will be appreciated that the service application may be configured to communicate with a plurality of different local host applications at different remote locations via the wide area network. For example, service application 136 may communicate with local host application 124 at the first location. As another example, service application 136 may communicate with local host applications at locations 2 through N generally referenced at 152. It will be appreciated that each location may include one or more local host application(s) and one or more gated power receptacle(s) in wireless communication with the one or more local host applications.

Continuing with FIG. 1, local host application 124 may be executable on a local host computing device 118 at the first location. Local host application 124 may be in wireless communication with the plurality of gated power receptacles 115 via local wireless network 116. Local wireless network 116 may be a wireless personal area network (WPAN). The wireless communication between the local host computing device and the gated power receptacles may occur according to a protocol selected from the IEEE 802.15 workgroup standard, such as, for example, Bluetooth or ZigBee. The ZigBec protocol may be suitably implemented in the system since wireless communication between the gated power receptacles and the local host application may be performed at a low data rate and the gated power receptacles may have low power consumption operating levels. Alternatively, in some embodiments, the local wireless network may be based on another wireless standard such as IEEE 802.11.

In one example, local host application 124 may send a wireless command signal to one or more of gated power receptacles 110, 112, and 114 via a wireless transceiver 122 controlled by a coordinator module 120 of local host computing device 118. Coordinator module 120 may be configured to manage operation of local wireless network 116 and may act as a bridge to other networks (e.g. WAN 132). In some embodiments, the coordinator module may store information about the local wireless network in local memory of the local host computing device, such as security keys of end devices, for example.

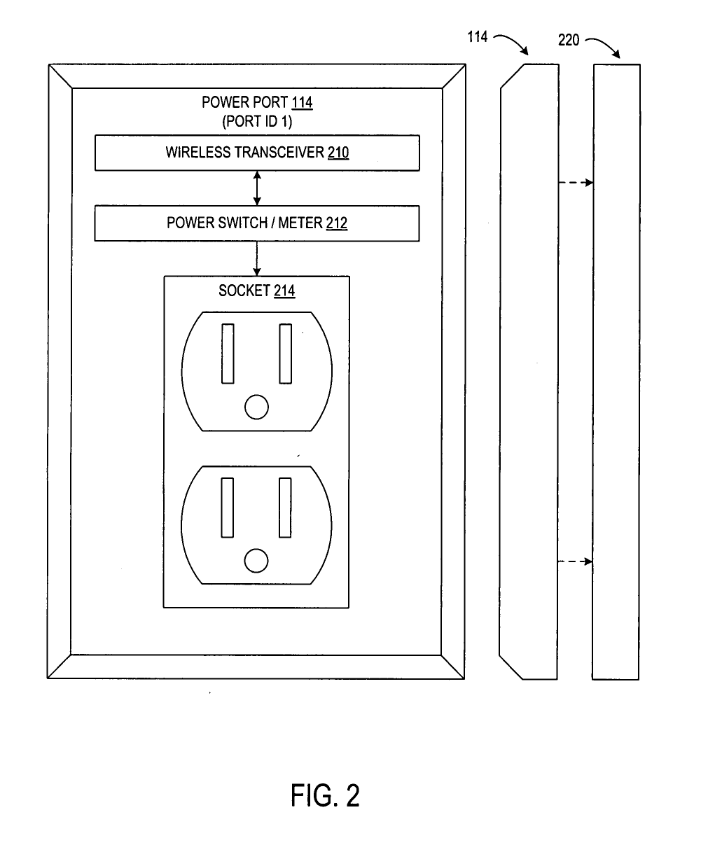

Furthermore, each of the plurality of gated power receptacles 115 may include respective wireless transceivers configured to enable wireless communication between the local host computing device and each of the plurality of gated power receptacles. The features and operation of the gated power receptacles will be discussed in further detail below with reference to FIG. 2.

The wireless command signals sent from the local host application to the gated power receptacles may be sent in response to receiving a communication from the service application. The wireless command signal may command the designated gated power receptacle to switch on electrical power. As discussed above, the gated power receptacle may be designated by a gated power receptacle identifier included in the communication sent from the service application.

Upon receiving a wireless command signal, a gated power receptacle may provide electrical power to an electronic device. In one example, the gated power receptacle may be configured to detect when current is being drawn from the gated power receptacle and may be configured to turn off electrical power upon detection of no current being drawn from the power receptacle. In some embodiments, electrical power may be turned off after a predetermined amount of time after detecting that no current is being drawn in order to account for an electrical plug dislodged from the gated power receptacle or a changing of devices, or the like.

Upon the electrical power being turned off at the gated power receptacle, the gated power receptacle may be configured to send a report to the local host application. The report may provide an indication to the local host application that the gated power receptacle is available for use.

In some embodiments, the report may include information relating to power usage during the duration in which the electrical power was turned on at the gated power receptacle. In one example, the information may be an amount of current drawn from the gated power receptacle during the duration. The coordinator module and/or the local host application may include logic to determine the amount of power consumed based on the amount of current drawn and the duration. In one example, the duration may be calculated based on the amount of time that elapses between sending the wireless command signal and receiving the report while subtracting operational and transmission delays.

Local host application 124 may be configured to aggregate or collect reports received from a plurality of gated power receptacles 115. In some embodiments, the aggregate report data corresponding to each session that each of the plurality of gated power receptacles provide power may be stored in local memory of the local host computing device. Local host application may be further configured to send aggregate report data based on reports from the plurality of gated power receptacles to service application 136 via WAN 132.

Application service 136 may receive aggregate report data from a plurality of local host applications at different locations. Upon receiving aggregate report data from a local host application corresponding to a location, service application 136 may be configured to determine an amount of electrical power consumed at each of the plurality of gated power receptacles at the location. Further, the service application may be configured to determine an amount of power consumed by a group of gated power receptacles or the total amount of power consumed at the location. In some embodiments, multiple locations may be organized into a single entity, such as, for example, a company having several stores. In this case, the service application may be configured to determine the total amount of power consumed for all of the locations of the entity. Application service 136 may store the determined power consumption data in data store 142 as usage data 144.

In some embodiments, electrical power may be selectively provided to a requesting user based one or more customizable business rules set at a local host application. In one example, a request for power to be provided at a gated power receptacle may be sent from a user device via a user device interface to the service application. In response to receiving the request, the service application and/or the user device interface may apply one or more business rules before processing the request. For example, applying one or more business rules may include sending the user device a reply to the request. The reply may be presentable on the user device and the reply may include a business rule or a proposition acceptable by the user device in order for the service application to send a communication to the host application to turn on electrical power at a designated gated power receptacle.

A non-limiting list of exemplary business rules that may be applied to a requesting user may include charging a one-time fee for a one-time use of electrical power, creating an a prepaid, debit, credit, or other account for repeated use of electrical power at various locations throughout system 100, and sending an advertisement or commercial to the user that is viewed in order to receive power. In some cases, business rules may be targeted or customized at each location based on the aggregate report data. For example, a user who is a registered account holder for repeated use of the gated power receptacles may receive targeted advertising based on the locations where the subscriber uses a gated power port. As another example, a gated power receptacle may be located proximate to a display of a featured item and a user may receive an advertisement including a coupon for the featured item. By applying business rules that include targeted advertising, the likelihood of a user purchasing goods may increase which in turn may generate increased revenue for establishments that employ the system.

Furthermore, different locations may customize business rules applied to user devices that request electrical power for a gated power receptacle at the location. In the illustrated embodiment, service application 136 may include local host application interface 140 that may be configured to enable customization of one or more business rules at different locations. Local host application interface 140 may be accessible to local host application 124, that is, server computing device 134 may serve local host application interface 140 to local host application 124, for example via a thin client application such as a web portal viewed via a browser. Further, local host application 124 may present various types of data of local host application interface 140 via graphical user interface (GUI) 126.

In one example, local host application 124 may be configured to display at least one of the amount of electrical power consumed at each of the plurality of gated power receptacles, the amount of electrical power consumed by a user, and the amount of power consumed by a group of gated power receptacles at a location corresponding to the local host application via a graphical user interface 126. The different types of displayed data may be indicated by local usage data 128. In some cases, local usage data 128 may be accessed locally via local memory of local host computing device 118. Further, in some cases local usage data 128 may be retrieved from data store 142 via local host application 140. By displaying the local usage data at the local host application, electrical power usage may be monitored for the particular location. Moreover, the local usage data may be used to analyze various electrical power usage statistics, and identify trends that may be related to frequency of use or other temporal factors. These statistics and trends may be used to optimize the operation, floor plan layout, advertising, etc., of the various locations.

Local host application 124 may be configured to present local business rules data 130 via GUI 126. Local business rules data 130 may include business rules currently being applied to requesting users at the location. In one example, the business rules may be set via user input into the local host computing device. The business rules may be customizable and may be adjusted based on the local usage data. Further, upon entering or changing business rules at local host application 124, the updated local business rules data may be sent to the service application via local host interface 140. The updated business rules data may be stored in data store 142 as business rules data 148. It will be appreciated that business rules data may include business rules aggregated from the plurality of local host application of the system. In some cases, multiple locations grouped under a single entity may share the same business rules which may be stored as business rule data 148 and may be accessed locally at each of the location via local user interface 140.

Turning now to FIG. 2, an exemplary embodiment of a gated power receptacle 114 is shown. Gated power receptacle 114 may be an adaptor configured to be romoveably coupled to an existing power receptacle 220. Gated power receptacle 114 may be removably coupled to existing power receptacle 220 via any suitable manner of coupling, including but not limited to screws, bolts, friction fit, glue, etc. In an alternative embodiment, the gated power receptacle may be a stand alone power receptacle. In still another embodiment, the gated power receptacle may be an extension of an existing power receptacle, such as an extension cord or power supply, for example.

Gated power receptacle 114 may include a wireless transceiver 210 for communicating with a remote local host application 124 via a local wireless network 116, such as a WPAN, for example. Wireless transceiver 210 may be configured to receive a wireless command signal from local host application 124. The wireless command signal may include an individual identifier that identifies the gated power receptacle. Further, wireless transceiver 210 may be configured to send a report signal to local host application 124. The report signal may indicate that the gated power receptacle is available for use.

Wireless transceiver 210 may be in electrical communication with a metering switch 212. Metering switch 212 may be configured to toggle between a first state and a second state based on the wireless command signal. The first state may be an “off” state in which no power is provided. The second state may be an “on” state in which power may be provided.

Gated power receptacle 114 may include socket 214 in electrical communication with metering switch 212. Socket 214 may be configured to pass through electrical power from existing power receptacle 220 to be output in response to metering switch 212 being placed in the second state. It will be appreciated that gated power receptacle 114 may include any suitable number of sockets without departing from the scope of the present disclosure.

In some embodiments, metering switch 212 may be configured to measure current drawn from the socket. In such embodiments, the report signal sent via the wireless transceiver may include an amount of current drawn from the gated power receptacle as measured when the metering switch is in the second state. Further, the metering switch may be configured to transition from the second state to the first state in response to detection of no current being drawn or power being consumed from the socket for a predetermined period. In an alternative embodiment, the metering switch may be configured to transition from the second state to the first state after a predetermined period of time regardless of whether or not power is being consumed. In one example, the above described embodiment may be employed in a business model where limited electrical power may be provided or electrical power may be provided on a prepaid basis.

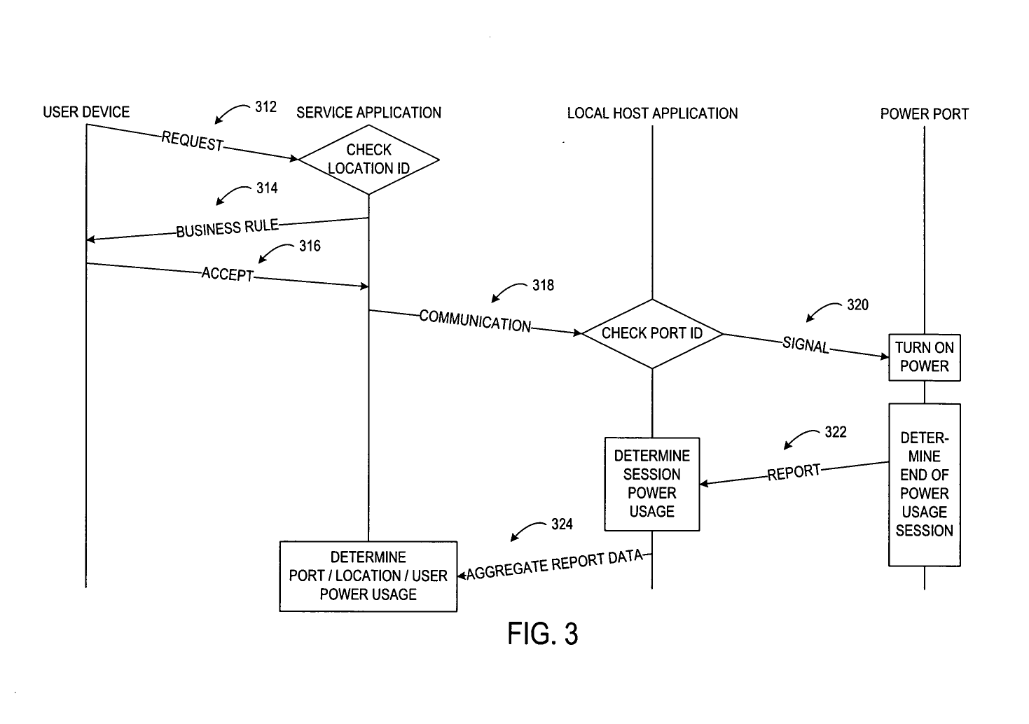

Turning now to FIG. 3, a communication flow diagram demonstrating an example of selectively providing electrical power at a designated gated power receptacle based on a user request is shown. At 312, a request may be sent from a user device to the service application. The request may be for electrical power to be provided at a gated power receptacle. The request may include an identifier that identifies the gated power receptacle and the location of the gated power receptacle. In one example, the identifier may be a numeric code that is labeled on a gated power receptacle. The identifier may be checked by the service application to determine where the user requested gated power receptacle is located so that a communication may be sent to the corresponding local host application.

At 314, in response to the request from the user device, the service application may send a reply which may include a business rule that may be applied to the user. As discussed above, the business rule may include different actions which the user may agree to perform in order to use electrical power. For example, the user may be requested to pay a fee, view an advertisement, fill out a survey, etc. The embodiment of the business rules may be presented to the user on the user device.

At 316, the user may accept the conditions of the business rule and the user device may send an accept signal to the service application.

At 318, a communication may be sent from the service application to the local host application in response to the service application receiving acceptance by the user of the business rule. The communication may be sent to the local host application based on the location identified in the identifier. The communication may include a command to turn on power at a gated power receptacle based on the identifier and the communication may include a gated power receptacle identifier. The local host application may check the communication to identify the gated power receptacle.

At 320, the local host application may send a wireless command signal to the gated power receptacle based on the identifier. The wireless command signal may command the gated power receptacle to switch to an on state in which electrical power may be supplied.

At 322, a report signal indicating that the gated power receptacle is available for use may be sent from the gated power receptacle to the local host application. The report may be, sent in response to the gated power receptacle determining that a power usage session has ended. As discussed above, the gated power supply may determine that no power is being consumed in a passive manner by measuring whether or not current is being drawn from the gated power receptacle or the gated power supply may actively switch to an off state after a duration to end a power usage session. The local host application may determine an amount of power consumed during the power usage session based on the duration from when the wireless command signal was sent and when the report signal was received as well as the amount of current drawn during the duration.

At 324, aggregate report data may be sent from the local host application to the service application. The aggregate report data may include power usage data for each of the power usage sessions of the gated power receptacles in wireless communication with the local host application. The service application may determine the power usage of each of the gated power receptacles at the location of the local host application, the total power usage of a group or all of the gated power receptacles associated with the local host application, and/or the total power usage of a registered user at the location of the local host application based on the aggregate report data. Furthermore, the service application may determine other power usage information based on receiving aggregate report data from a plurality of local host applications.

The above described example illustrates how electrical power may be selectively provided at different locations based on control by a centralized application. By implementing a centralized service application to control a plurality of wireless remote gated power receptacles system infrastructure may be reduced which in turn may reduce system costs. Moreover, the centralized service application may enable data mining that may provide usage information based on the operation of the plurality of gated power receptacles. The usage information may be analyzed at a high level or at a finer granularity such as on a local scale. The usage information may provide insight which may be used to manage operations, marketing, etc;.

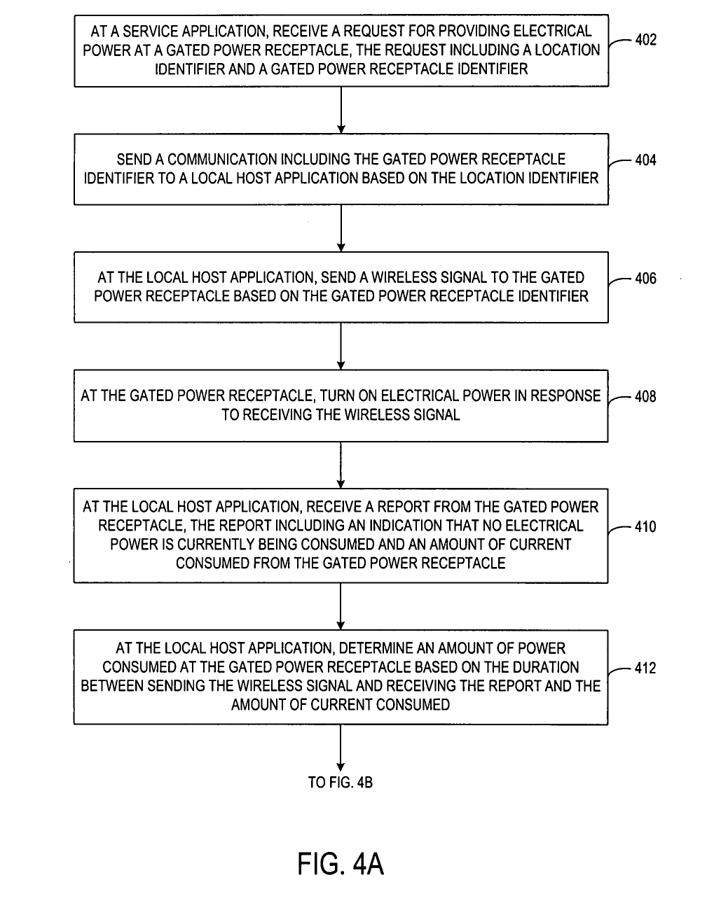

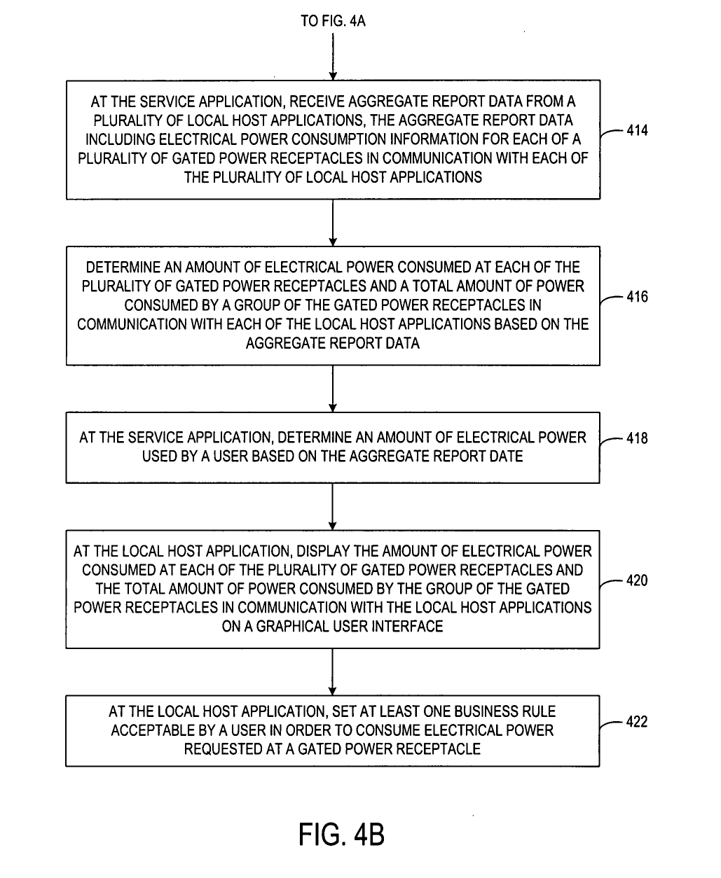

Turning now to FIGS. 4A-4B, one embodiment a method for selectively providing electrical power is shown. At 402, the method typically includes at a service application, receiving a request for providing electrical power at a gated power receptacle, the request including a location identifier and a gated power receptacle identifier. In one example, the request may include an address or a header that further may include a first numeric code section corresponding to the location identifier and a second numeric code section corresponding to the gated power receptacle identifier.

At 404, the method may include sending a communication including the gated power receptacle identifier to a local host application based on the location identifier. The communication may include the gated power receptacle identifier.

At 406 the method may include at the local host application, sending a wireless signal to the gated power receptacle based on the gated power receptacle identifier. In some cases, the wireless signal may be a command to switch to an on state to provide electrical power at the gated power receptacle.

At 408, the method may include at the gated power receptacle, tuning on electrical power in response to receiving the wireless signal.

At 410, the method may include at the local host application, receiving a report from the gated power receptacle. The report may include an indication that the gated power receptacle is available for use or that no electrical power is currently being consumed. Further, the report may include an amount of current drawn from the gated power receptacle.

At 412, the method may include at the local host application, determining an amount of power consumed at the gated power receptacle based on the duration between sending the wireless signal and receiving the report as well as the amount of current drawn during the duration.

At 414, the method may include at the service application, receiving aggregate report data from a plurality of local host applications. The aggregate report data may include electrical power consumption information for each of a plurality of gated power receptacles in communication with each of the plurality of local host applications.

At 416, the method may include determining an amount of electrical power consumed at each of the plurality of gated power receptacles and a total amount of electrical power consumed by a group of the gated power receptacles in communication with each of the local host applications based on the aggregate report data.

At 418, the method may include at the service application, determining an amount of electrical power consumed by a user based on the aggregate report data.

At 420, the method may include at the local host application, displaying the amount of electrical power consumed at each of the plurality of gated power receptacles and the total amount of power consumed by the group of the gated power receptacles in communication with the local host application on a graphical user interface.

At 422, the method may include at the local host application setting at least one business rule acceptable by a user in order to consume electrical power requested at a gated power receptacle.

The above described methods may enable a plurality gated power receptacles to be controlled from a centralized remote location. By implementing centralized control the plurality of gated power receptacle may be metered and the resulting data may be analyzed from a high level perspective. The high level analysis may be used to advantage to generate revenue and/or optimize the management, operations, marketing, floor plan layout, etc., of the location.

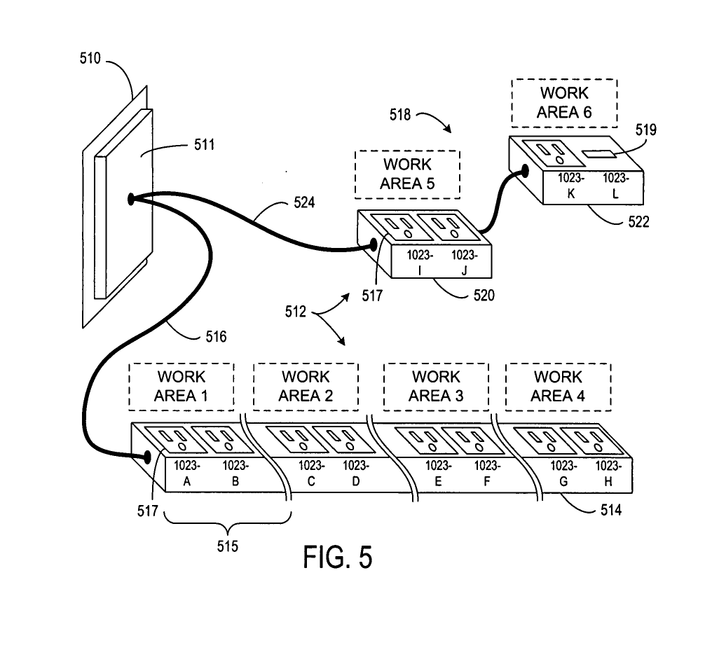

Turning now to FIG. 5, in one embodiment, multiple gated power receptacles 517 may be grouped into one or more power distribution units 512. Further, multiple power distribution units 512 may be connected to one another and may be supplied with electrical power from a source 510. In this way, a suitable number of power receptacles 517 may be made available to provide access to electrical power in high density power consumption areas.

As illustrated, multiple gated power receptacles 517 may be grouped into one or more power distribution units 512, including an elongated power strip 514 and compact power pods 518. Electrical power may be supplied to power strip 514 from power source 510, in this example a wall outlet, via a power port 511 including an internal wireless transceiver and power switch/meter, which function as described above. Typically, no power receptacles are provided on the body of power port 511, although they are not precluded. One or more cords 516 may extend from a face of the power port 511 to power strip 514, and power pods 518. The cords 516 typically carry power and gating signals to each of the receptacles, to control the power flow at each receptacle as described above.

Power strip 514 may include zones 515 that each correspond to a different work areas. Each zone may include one or more (two in the depicted embodiment) gated power receptacles to provide electrical power to a corresponding work area. If desired, power may be gated on a zone by zone basis, or on a receptacle by receptacle basis, although the latter is typically envisioned. Each gated power receptacle may be labeled with an identifier (e.g. 1023-A through 1023-L in FIG. 5), which enables a user to indicate the gated power receptacle at which electrical power may be desired.

As one example, the elongated power strip 514 may be used in an airport setting where a group of people may be waiting for a flight in a waiting area with elongated rows of chairs. While waiting, electrical devices may be used to pass the time and there may be a likelihood that the area may have a high demand for power consumption. In one non-limiting example, an elongated power strip 514 may be installed in proximity to one of the elongated rows of seats in the waiting area. Each zone 515 of the power strip 514 may correspond to a particular seat or group of seats. People who wish to receive electrical power to operate an electrical device may use the identifier presented on a particular gated power receptacle of the elongated power strip 514 to request power be supplied to the gated power receptacle 517 according to the methods discussed above.

The gated receptacles 517 may be of a variety of shapes and power configurations, such as two-pin or three-pin configurations, and may be grounded or include a ground fault circuit interrupter. The gated receptacles 517 may be configured to provide alternating current (AC) power, or may include an associated transformer and be configured to provide direct current (DC) power. Further, the gated receptacles 517 may include a USB charge station receptacle 519 configured to receive a USB connector and provide an associated USB device with power to recharge the device.

It will be appreciated that the elongated power strip 514 may include any suitable number of electrical power zones 515 and each zone 515 may include any suitable number of gated power receptacles 517. Further, it will be appreciated that an elongated power strip may receive electrical power from a single source 510 or multiple sources and that the power may be supplied from an external source such as a wall outlet that the elongated power strip may be plugged into or electrical power maybe directly supplied to the elongated power strip. In some cases, one or more elongated power strips may be plugged into a different elongated power strip and electrical power may be supplied in a scalable manner.

Continuing with FIG. 5, compact power pods 518 are illustrated as connected in series. In particular, a first pod 520 may be connected in series to second pod 522 via a cord 524 for carrying power and gating signals. Each of pods 520 and 522 may include one or more gated receptacles 517 each having identifiers. The series of compact power pods may be supplied electrical power from a shared source 510. When connected in series, gating signals controlling power flow to each of the receptacles on downstream pods are typically routed from the power port 511 through to downstream pods. In this configuration, each compact power pod may correspond to a different work area. Additional power pods may be connected in series to facilitate access to electrical power at additional work areas in a scalable manner.

For example, the compact power pods connected in series may be placed in a coffee shop, library, or other setting where people may gather at tables. The scalable nature of the series of elongate power strips and compact power pods described above may be adaptable to changes in floor plan of the building so that more or less access to electrical power may be provided.

It will be appreciated that the computing devices described herein may be any suitable computing device configured to execute the programs and display the graphical user interfaces described herein. For example, the computing devices may be a personal computer, laptop computer, portable data assistant (PDA), computer-enabled wireless telephone, networked computing device, or other suitable computing device, and may be connected to each other via computer networks, such as the Internet or a wireless personal area network. These computing devices typically include a processor and associated volatile and memory, and are configured to execute programs stored in memory using portions of volatile memory and the processor. As used herein, the term “program” refers to software or firmware components that may be executed by, or utilized by, one or more computing devices described herein, and is meant to encompass individual or groups of executable files, data files, libraries, drivers, scripts, database records, etc. It will be appreciated that computer-readable media may be provided having program instructions stored thereon, which upon execution by a computing device, cause the computing device to execute the methods described above and cause operation of the systems described above.

It should be understood that the embodiments herein are illustrative and not restrictive, since the scope of the invention is defined by the appended claims rather than by the description preceding them, and all changes that fall within metes and bounds of the claims, or equivalence of such metes and bounds thereof are therefore intended to be embraced by the claims.

1. An electrical power metering system, comprising:
a plurality of gated power receptacles, each of the gated power receptacles configured to selectively provide electrical power in response to receiving a wireless signal;
a service application configured to receive a request to provide electrical power for one of the plurality of gated power receptacles, the request including an identifier that designates the one of the plurality of gated power receptacles at which electrical power is requested; and
a local host application executable on a computing device, the local host application configured to send the wireless signal via a coordinator module to the one of the plurality of gated power receptacles to provide electrical power in response to receiving a communication from the service application that includes the identifier.

2. The system of claim 1, wherein each of the plurality of gated power receptacles and the computing device include respective transceivers configured to enable wireless communication between the computing device and each of the plurality of gated power receptacles.

3. The system of claim 1, wherein the service application is executable on a server that is configured to communicate with the computing device via a wide area network, and wherein the service application includes a user device interface configured to apply at least one business rule in response to receiving the request from a user device.

4. The system of claim 3, wherein the service application further includes a local host application interface configured to enable customization of the at least one business rule and present power usage data corresponding to the plurality of gated power receptacles, the local host application interface being accessible from the local host application.

5. The system of claim 4, wherein the user device interface is configured to apply the at least one business rule at least in part by sending the user device a reply to the request, the reply being presentable on the user device and the reply including a businesses rule acceptable by the user device in order for the service application to send the communication to the local host application.

6. The system of claim 1, wherein the one of the gated power receptacles is further configured to turn off electrical power and send a report to the local host application in response to determining that no power is being consumed at the one of the gated power receptacles.

7. The system of claim 6, wherein the report includes an amount of current drawn during the duration in which the one of the gated power receptacles was turned on, and wherein local host unit is further configured to send aggregate report data based on reports from the plurality of gated power receptacles to the service application.

8. The system of claim 7, wherein the service application is further configured to determine at least one of an amount of electrical power consumed at each of the plurality of gated power receptacles, an amount of electrical power consumed by a user, and an amount of power consumed by a group of gated power receptacles at a location corresponding to the local host application based on the aggregate report data.

9. The system of claim 8, wherein the local host application is further configured to display the at least one of the amount of electrical power consumed at each of the plurality of gated power receptacles, the amount of electrical power consumed by a user, and the amount of power consumed by a group of gated power receptacles at a location corresponding to the local host application via a graphical user interface.

10. The system of claim 1, wherein the request is user generated according to at least one of short message service (SMS), interactive voice response (IVR), and hyper text transfer protocol (HTTP).

11. A method for metering electrical power, comprising:
at a service application, receiving a request to provide electrical power at a gated power receptacle, the request including a location identifier and a gated power receptacle identifier;
sending a communication including the gated power receptacle identifier to a local host application based on the location identifier;
at the local host application, sending a wireless signal to the gated power receptacle based on the gated power receptacle identifier; and
at the gated power receptacle, turning on electrical power in response to receiving the wireless signal.

12. The method of claim 11, further comprising:
at the local host, receiving a report from the gated power receptacle, the report including an indication that no electrical power is currently being consumed.

13. The method of claim 12, further comprising:
at the local host, determining an amount of power consumed at the gated power receptacle based on the duration between sending the wireless signal and receiving the report.

14. The method of claim 11, further comprising:
at the service application, receiving aggregate report data from a plurality of local host applications, the aggregate report data including electrical power consumption information for each of a plurality of gated power receptacles in communication with each of the plurality of local host applications; and
determining an amount of electrical power consumed at each of the plurality of gated power receptacles and a total amount of power consumed by a group of the gated power receptacles in communication with each of the local host applications based on the aggregate report data.

15. The method of claim 14, further comprising:
at the service application, determining an amount of electrical power usage of a user based on the aggregate report data.

16. A gated power receptacle adaptor configured to be removably coupled to an existing power receptacle, the gated power adaptor comprising:
a wireless transceiver for communicating with a remote local host application via a wireless personal area network, the wireless transceiver configured to receive a wireless command signal from the local host application;
a metering switch in electrical communication with the wireless transceiver, the metering switch configured to toggle between a first state for not providing electrical power and a second state for providing electrical power, the metering switch toggling from the first state and the second state based on the wireless command signal; and
a socket configured to pass through power from the existing power receptacle to be output in response to the metering switch being placed in the second state.

17. The adaptor of claim 16, wherein the metering switch is further configured to measure current drawn from the socket when the switch is in the second state.

18. The adaptor of claim 17, wherein wireless transceiver is further configured to send a report signal to the local host application via the wireless personal area network, the report signal include the amount of current drawn as measured by the metering switch.

19. The adaptor of claim 16, wherein the adaptor is designated by an individual identifier and the wireless command signal is sent to the wireless transceiver based on the individual identifier.

20. The adaptor of claim 16, wherein the metering switch is further configured to transition from the second state to the first state in response to detection of no power being consumed from the socket for a predetermined period.
